(19) United States
(12) Patent Application Publication
(10) Pub. No.: US 2025/0306109 A1
(43) Pub. Date: Oct. 2, 2025

(54) DETERMINATION DEVICE, DETERMINATION METHOD, AND STORAGE MEDIUM

(71) Applicant: HONDA MOTOR CO., LTD., Tokyo (JP)

(72) Inventors: Takaharu Watanabe, Wako-shi (JP); Pu Qian, Wako-shi (JP); Shiori Nakanishi, Wako-shi (JP); Kota Ogasawara, Wako-shi (JP); Wataru Hoshikawa, Wako-shi (JP)

(21) Appl. No.: 19/056,796

(22) Filed: Feb. 19, 2025

(30) Foreign Application Priority Data
Mar. 28, 2024 (JP) 2024-053961

(51) Int. Cl. G01R 31/36; G01R 31/3842; H02J 7/00

(52) U.S. Cl. CPC G01R 31/3648; G01R 31/3842; H02J 7/0047; H02J 7/0068

(57) ABSTRACT

Provided is determination device including a processor. The processor is configured to: acquire a relaxation curve of voltage of a lithium metal battery having a negative electrode containing lithium; and determine a recommended-suppression time of recommending suppression of charging and discharging of the lithium metal battery based on a rate of change of voltage in a short time constant range corresponding to a range of a short time constant in the relaxation curve.

### CROSS-REFERENCE TO RELATED APPLICATION

Priority is claimed on Japanese Patent Application No. 2024-053961, filed Mar. 28, 2024, the content of which is incorporated herein by reference.

### BACKGROUND OF THE INVENTION

### Field of the Invention

The present invention relates to a determination device, a determination method, and a storage medium.

### Description of Related Art

In recent years, in order to ensure that more people can have access to affordable, reliable, sustainable, and advanced energy, research and development has been conducted to contribute to energy efficiency. With regard to such a technology, lithium metal batteries using lithium metal for a negative electrode have attracted attention as a secondary battery (for example, see PCT International Publication No. WO 2023/118960, Japanese Unexamined Patent Application, First Publication No. 2023-17581, and Japanese Unexamined Patent Application, First Publication No. 2022-113377). A lithium metal battery includes a positive electrode, a negative electrode having a metallic lithium layer, and an electrolyte disposed between the positive electrode and the negative electrode.

Incidentally, lithium-ion batteries not containing lithium in the negative electrode exhibit robustness in mitigating a transient increase in resistance that occurs when the batteries are repeatedly charged and discharged. However, lithium metal batteries have low robustness against a transient increase in resistance, and there is a concern that lithium metal batteries may permanently deteriorate if charging and discharging are repeatedly performed in succession. Therefore, it is desirable to suppress permanent deterioration by, for example, avoiding repeated charging and discharging in succession.

The invention has been made in consideration of such circumstances, and an object thereof is to suppress deterioration of lithium metal batteries. Furthermore, this contributes to energy efficiency.

### SUMMARY OF THE INVENTION

A determination device, a determination method, and a storage medium according to the invention employ the following configuration.

(1) A determination device according to one aspect of the invention includes a processor. The processor is configured to: acquire a relaxation curve of voltage of a lithium metal battery having a negative electrode containing lithium; and determine a recommended-suppression time of recommending suppression of charging and discharging of the lithium metal battery based on a rate of change of voltage in a short time constant range corresponding to a range of a short time constant in the relaxation curve.
(2) In the above-described aspect (1), the processor is configured to acquire the relaxation curve generated based on a charge-discharge history of the lithium metal battery.
(3) In the above-described aspect (1), the processor is configured to determine that the recommended-suppression time is longer when the rate of change is less than or equal to a specified value than when the rate of change exceeds the specified value.
(4) In the above-described aspect (1), the processor is configured to determine the recommended-suppression time by referring to a suppression time control map in which the recommended-suppression time is set to be longer when the rate of change is less than or equal to a specified value than when the rate of change exceeds the specified value.
(5) In the above-described aspect (1), the processor is configured to switch a control mode between a first control mode of controlling the lithium metal battery and a second control mode in which a load on the lithium metal battery is smaller than that in the first control mode.
(6) In the above-described aspect (5), the processor is configured to provide information related to the recommended-suppression time to a user and accepts a designation of the control mode by the user, and the processor is configured to switch the control mode based on the designation.
(7) In the above-described aspect (6), the information related to the recommended-suppression time includes the recommended-suppression time.
(8) In the above-described aspect (1), the lithium metal battery is mounted in a vehicle.
(9) A determination method according to one aspect of the invention is a determination method causing a computer to: acquire a relaxation curve of voltage of a lithium metal battery having a negative electrode containing lithium; and determine a recommended-suppression time of recommending suppression of charging and discharging of the lithium metal battery based on a rate of change of voltage in a short time constant range corresponding to a range of a short time constant in the relaxation curve.
(10) A storage medium according to one aspect of the invention is a computer-readable non-transitory storage medium storing a program. The program causes a computer to: acquire a relaxation curve of voltage of a lithium metal battery having a negative electrode containing lithium; and determine a recommended-suppression time of recommending suppression of charging and discharging of the lithium metal battery based on a rate of change of voltage in a short time constant range corresponding to a range of a short time constant in the relaxation curve.

According to the aspects (1) to (10), deterioration of lithium metal batteries can be suppressed.

### BRIEF DESCRIPTION OF THE DRAWINGS

FIG. 1 is a diagram showing an example of a configuration of a vehicle M in which a determination device 100 of an embodiment is mounted.

FIG. 2 is a diagram showing an example of a configuration of the determination device 100.

FIG. 3 is a diagram showing an example of a visualized rest time control map 122.

FIG. 4 is a diagram showing an example of a relaxation curve of a lithium metal battery 10 after charging and discharging.

FIG. 5 is a diagram showing an example of a configuration of an ECU 200.

FIG. 6 is a flowchart showing an example of processing of the determination device 100.

FIG. 7 is a flowchart showing an example of processing of the ECU 200.

FIG. 8 is a diagram showing an example of a display screen of an input/output interface 43 that displays recommended rest information.

### DETAILED DESCRIPTION OF THE INVENTION

Hereinafter, embodiments of a determination device, a determination method, and a storage medium of the invention will be described with reference to the drawings.

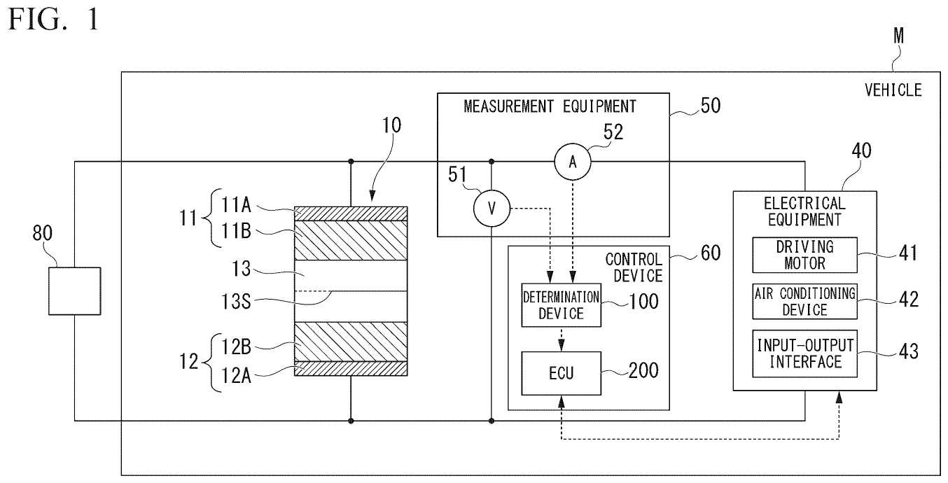

FIG. 1 is a diagram showing an example of a configuration of a vehicle M in which a determination device 100 of an embodiment is mounted. The determination device 100 of the embodiment determines a deterioration state of a lithium metal battery 10 mounted in the vehicle M. The lithium metal battery 10 includes a negative electrode containing lithium. The lithium metal battery 10 is a secondary battery that is capable of being charged and discharged.

In addition to the lithium metal battery 10, electrical equipment 40, measurement equipment 50, and a control device 60 are mounted in the vehicle M. The electrical equipment 40 includes, for example, a driving motor 41, an air conditioning device 42, and an input/output interface 43. The measurement equipment 50 includes, for example, a voltage detector 51 and a current detector 52. The control device 60 includes, for example, the determination device 100 and an electronic control unit (ECU) 200.

The lithium metal battery 10 is, for example, a semi-solid-state battery. The lithium metal battery 10 includes, for example, a positive electrode 11, a negative electrode 12, and an electrolyte 13. The positive electrode 11 includes, for example, a positive electrode current collector 11A and a positive electrode active material layer 11B. The positive electrode current collector 11A is formed of, for example, a current collector foil such as aluminum. The positive electrode active material layer 11B is formed of, for example, a layer such as that of lithium cobalt oxide.

The negative electrode 12 includes, for example, a negative electrode current collector 12A and a negative electrode active material layer 12B. The negative electrode current collector 12A is formed of, for example, a current collector foil such as copper. The negative electrode active material layer 12B is formed of, for example, a metallic lithium layer. The electrolyte 13 is a semi-solid electrolyte containing lithium ions Li+. The electrolyte 13 is partitioned into the side of the positive electrode 11 and the side of the negative electrode 12 by a separator 13S.

During discharge, when the lithium metal battery 10 supplies power to the electrical equipment 40 mounted in the vehicle M, the lithium ions Li+ flow from the negative electrode active material layer 12B to the positive electrode 11 through the separator 13S. Along with the flow of lithium ions Li+, electrons e flow from the negative electrode 12 to the positive electrode 11 through a circuit of the electrical equipment 40. Due to the flow of lithium ions Li+ and electrons e, a current flows from the side of the positive electrode 11 to the side of the negative electrode 12, and the lithium metal battery 10 is discharged. In the negative electrode active material layer 12B, metallic lithium dissolves as the lithium metal battery 10 is discharged.

The lithium metal battery 10 is charged by a charging facility 80 outside the vehicle M. The charging facility 80 is provided, for example, at a home of the owner of the vehicle M, a charging station, or the like. During charging, lithium ions Li+ flow from the positive electrode active material layer 11B to the side of the negative electrode 12 through the separator 13S.

Along with the flow of lithium ions Li+, electrons e flow from the positive electrode 11 to the side of the negative electrode 12 through the charging facility 80. Due to the flow of lithium ions Li+ and electrons e, a current flows from the side of the negative electrode 12 to the side of the positive electrode 11, and the lithium metal battery 10 is charged. In the negative electrode active material layer 12B, metallic lithium is deposited as the lithium metal battery 10 is charged.

The driving motor 41 in the electrical equipment 40 is, for example, an electric motor. An output shaft of the driving motor 41 is connected to an input shaft of a drive-side reduction gear and applies a driving force to a wheel connected to a drive reduction mechanism. The air conditioning device 42 is, for example, an air conditioner, and adjusts a temperature of an air inside an interior of the vehicle M. The input/output interface 43 is, for example, a touch panel. The touch panel is attached, for example, to an instrument panel inside the vehicle interior.

The input/output interface 43 may have an input interface and an output interface provided separately. In this case, the input interface may be, for example, a button (switch) provided on a steering wheel or an instrument panel, and the output interface may be, for example, a display.

The voltage detector 51 in the measurement equipment 50 detects a voltage value between terminals of the lithium metal battery 10. The voltage detector 51 outputs the detected voltage value to the determination device 100 of the control device 60. The current detector 52 detects a current value of a current flowing from the side of the positive electrode 11 to the side of the negative electrode 12 of the lithium metal battery 10. The current detector 52 outputs the detected current value to the determination device 100.

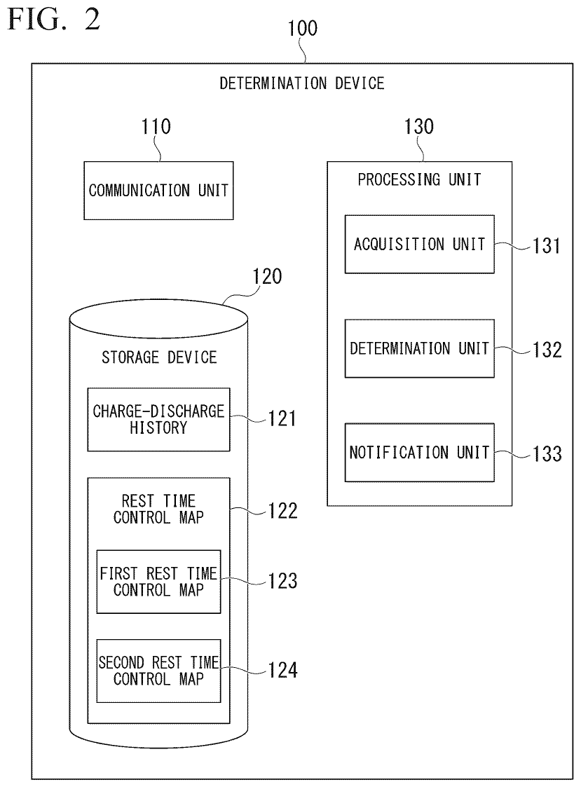

FIG. 2 is a diagram showing an example of a configuration of the determination device 100. The determination device 100 includes, for example, a communication unit 110, a storage unit 120, and a processing unit 130. The communication unit 110 performs transmission and reception of signals between the determination device 100 and an external device. The communication unit 110 transmits, for example, a current supply signal generated by the processing unit 130 to an AC power supply 20. The communication unit 110 receives a current signal transmitted by the current detector 52. The transmission and reception performed by the communication unit 110 may be wired communication via wiring, or wireless communication via a network.

The storage unit 120 is formed of, for example, a hard disk drive (HDD), a flash memory, and the like. The storage unit 120 may be a drive device or the like that is externally attached to the control device 60. The storage unit 120 stores a charge-discharge history 121 and a rest time control map 122. The rest time control map 122 includes, for example, a first rest time control map 123 and a second rest time control map 124.

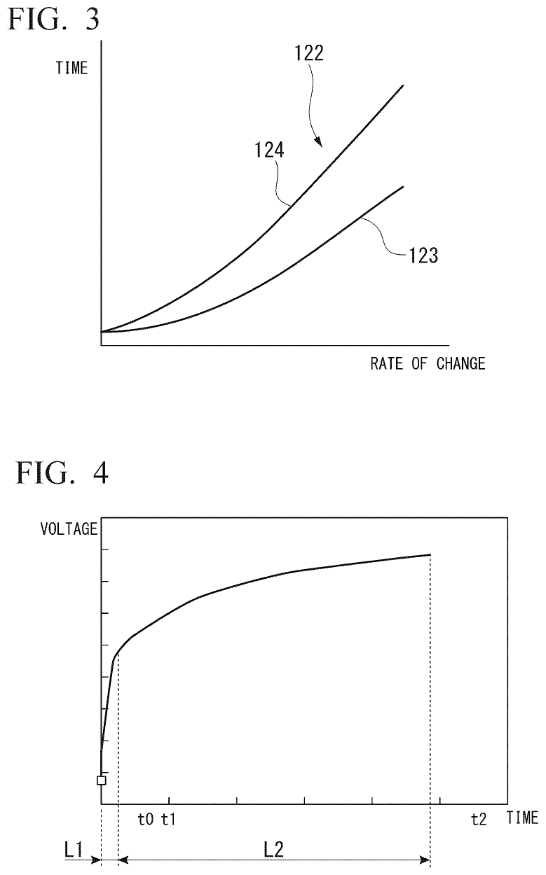

FIG. 3 is a diagram showing an example of the visualized rest time control map 122. The first rest time control map 123 and the second rest time control map 124 in the rest time control map 122 are both maps indicating a rest time according to a rate of change of voltage discharged by the lithium metal battery. Both the first rest time control map 123 and the second rest time control map 124 are maps in which the rest time becomes longer as a rate of change of the voltage increases. The rest time control map 122 is an example of a suppression time control map.

The processing unit 130 includes, for example, an acquisition unit 131, a determination unit 132, and a notification unit 133. These components are realized by, for example, a hardware processor such as a central processing unit (CPU) executing a program (software). Some or all of these components may be realized by hardware (circuit unit including a circuitry) such as a large scale integration (LSI), an application specific integrated circuit (ASIC), a field-programmable gate array (FPGA), and a graphics processing unit (GPU), or may be realized by software and hardware in cooperation.

The program may be stored in the storage unit 120 (a storage device having a non-transitory storage medium) such as an HDD or a flash memory in advance, or may be stored in a detachable storage medium (non-transitory storage medium) such as a DVD or a CD-ROM and installed when the storage medium is loaded into a drive device.

The acquisition unit 131 acquires a voltage value output by the voltage detector 51 and a current value output by the current detector 52. The acquisition unit 131 adds the acquired voltage value and current value to a charge-discharge history stored in the storage unit 120. The acquisition unit 131 updates the charge-discharge history 121 by adding the voltage value and the current value.

The acquisition unit 131 acquires a charge-discharge request when charging and discharging is required for the lithium metal battery 10 based on, for example, detection results of the voltage detector 51 and the current detector 52 and operating status of the driving motor 41 and the air conditioning device 42 transmitted by the ECU 200. The acquisition unit 131, upon acquiring the charge-discharge request, reads the charge-discharge history 121 stored in the storage unit 120, and generates and acquires a relaxation curve of voltage of the lithium metal battery 10 based on the charge-discharge history 121. The charge-discharge history 121 includes information on the history of charging and discharging performed by the lithium metal battery 10. The relaxation curve is a curve that shows a voltage discharged from the lithium metal battery 10 within a certain period of time after the lithium metal battery 10 starts charging or discharging.

FIG. 4 is a diagram showing an example of a relaxation curve of the lithium metal battery 10 after charging and discharging. The lithium metal battery 10, for example, exhibits a relaxation curve in which a rate of change in voltage is high after charging or discharging is completed and then becomes smaller as time elapses. The relaxation curve varies in shape depending on each individual lithium metal battery 10. The acquisition unit 131, for example, normalizes a plurality of charge-discharge histories 121 stored in the storage unit 120 to generate and obtain a relaxation curve.

The determination unit 132 determines a recommended-suppression time of recommending suppression of charging and discharging of the lithium metal battery 10 based on a rate of change of voltage in a short time constant range corresponding to a range of short time constants in the relaxation curve obtained by the acquisition unit 131. For example, the relaxation curve shown in FIG. 4 includes a short time constant range L1 corresponding to a range of short time constants and a long time constant range L2 corresponding to a range of long time constants. The short time constant range L1 is a range from time t0 to time t1, and the long time constant range L2 is a range from time t1 to time t2. The short time constant range L1 is a range of time constants that is shorter than the long time constant range L2.

The determination unit 132 calculates a rate of change of voltage in the short time constant range L1 based on the relaxation curve shown in FIG. 4. The determination unit 132 determines a recommended rest time of recommending suppression, for example, rest, of charging and discharging of the lithium metal battery 10 based on the calculated rate of change. The recommended rest time is an example of a recommended-suppression time.

The determination unit 132 determines, for example, whether the calculated rate of change is less than or equal to a preset specified value. When the calculated rate of change is less than or equal to the specified value, the determination unit 132 determines the recommended rest time to be longer than when the rate of change exceeds the specified value. Specifically, when the calculated rate of change is less than or equal to the specified value, the determination unit 132 determines the recommended rest time by referring to the second rest time control map in which the recommended rest time is set to be longer than the first rest time control map which is referenced when the rate of change exceeds the specified value.

The notification unit 133 notifies the ECU 200 of information on the recommended rest time determined by the determination unit 132.

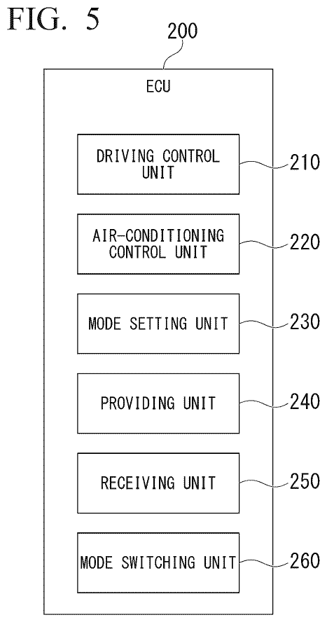

FIG. 5 is a diagram showing an example of a configuration of the ECU 200. The ECU 200 includes, for example, a driving control unit 210, an air-conditioning control unit 220, a mode setting unit 230, a providing unit 240, a receiving unit 250, and a mode switching unit 260. The ECU 200 is realized by, for example, a hardware processor such as a CPU executing a program (software) similarly to the processing unit 130 of the determination device 100. The ECU 200 may be realized by, for example, other methods similar to the processing unit 130 of the determination device 100.

The driving control unit 210 executes a control of causing the vehicle M to travel. The driving control unit 210 controls the driving motor 41 by transmitting a drive signal to the driving motor 41 based on an operation request signal or the like based on, for example, an operation of an accelerator pedal or a brake pedal. The air-conditioning control unit 220 controls the air conditioning device 42 to adjust a temperature inside the vehicle interior.

The mode setting unit 230 sets a control mode related to a control of the vehicle M including the lithium metal battery 10. As the control mode, the mode setting unit 230 sets, for example, either a normal mode that is used normally or an eco-mode in which a load on the lithium metal battery 10 is smaller than that in the normal mode. The normal mode is an example of a first control mode. The eco-mode is an example of a second control mode.

In the normal mode, both the driving control unit 210 and the air-conditioning control unit 220 execute a normal control. In the eco-mode, the driving control unit 210 reduces the load on the lithium metal battery 10 by suppressing rapid acceleration/deceleration and sudden braking. In the eco-mode, the air-conditioning control unit 220 reduces the load on the lithium metal battery 10 by increasing a setting temperature or reducing an amount of airflow compared to the normal mode.

The providing unit 240 detects operating status of the driving motor 41 and the air conditioning device 42 and transmits the detected operating status to the determination device 100. The providing unit 240 provides a user with information related to the recommended-suppression time. The providing unit 240 acquires the recommended rest time notified by, for example, the notification unit 133 in the processing unit 130 of the determination device 100. The providing unit 240 generates recommended rest information according to the acquired recommended rest time, transmits it to the input/output interface 43, and displays it on the input/output interface 43, thereby providing the recommended rest information to an occupant. The occupant is an example of a user.

The input/output interface 43 generates an image based on the transmitted recommended rest information and displays it on a display screen. The image displayed on the display screen includes a control mode designation switch. The input/output interface 43 generates switching information according to the control mode designation switch operated by the occupant of the vehicle M, and transmits it to the ECU 200. The switching information includes information of designating a control mode by the occupant.

The receiving unit 250 receives and accepts the switching information transmitted by the input/output interface 43, thereby accepting the control mode designated by the occupant. The mode switching unit 260 recognizes the occupant's designation based on the switching information received by the receiving unit 250. The mode switching unit 260 switches the control mode between the normal mode and the eco-mode based on the recognized designation of the occupant.

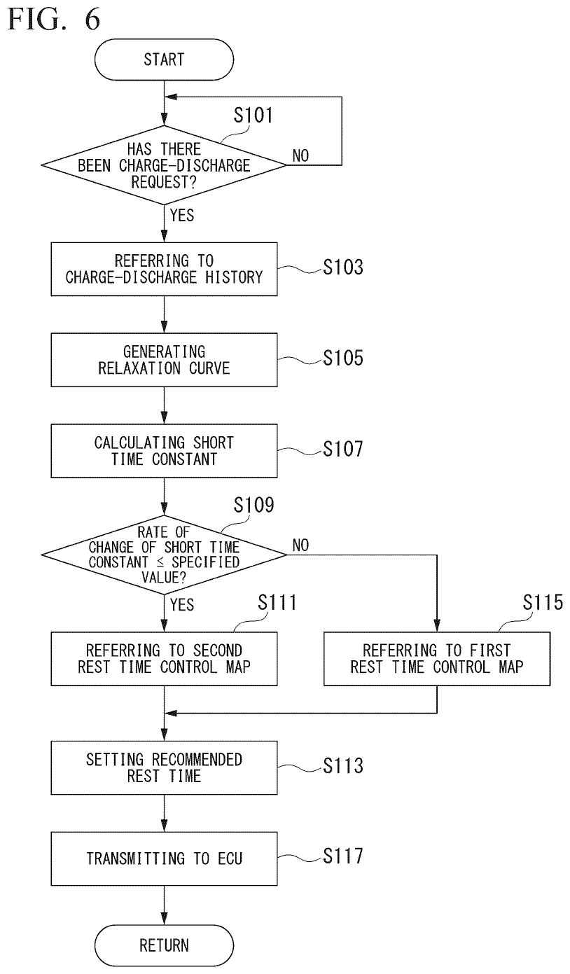

Next, regarding processing in the control device 60 of the embodiment, processing in the determination device 100 and processing in the ECU 200 will be described. FIG. 6 is a flowchart showing an example of processing in the determination device 100. In the determination device 100, first, it is determined whether or not the acquisition unit 131 has acquired a charge-discharge request (step S101).

If it is determined that the charge-discharge request has not been acquired, the acquisition unit 131 repeats the processing of step S101. If it is determined that a charge-discharge request has been acquired, the acquisition unit 131 refers to the charge-discharge history stored in the storage unit 120 (step S103). Next, the acquisition unit 131 generates a relaxation curve based on the acquired charge-discharge history (step S105).

Next, the determination unit 132 identifies a short time constant of the relaxation curve generated by the acquisition unit 131 (step S107). Next, the determination unit 132 calculates a rate of change of the voltage in the short time constant range L1 based on the identified short time constant, and determines whether the calculated rate of change is less than or equal to a specified value (step S109).

If it is determined that the calculated rate of change is less than or equal to the specified value, the determination unit 132 reads the second rest time control map 124 (step S111), and sets a recommended rest time based on the second rest time control map 124 (step S113). On the other hand, if it is determined that the calculated rate of change exceeds the specified value (is not less than or equal to the specified value), the determination unit 132 reads the first rest time control map 123 and sets the recommended rest time based on the first rest time control map 123 (step S115).

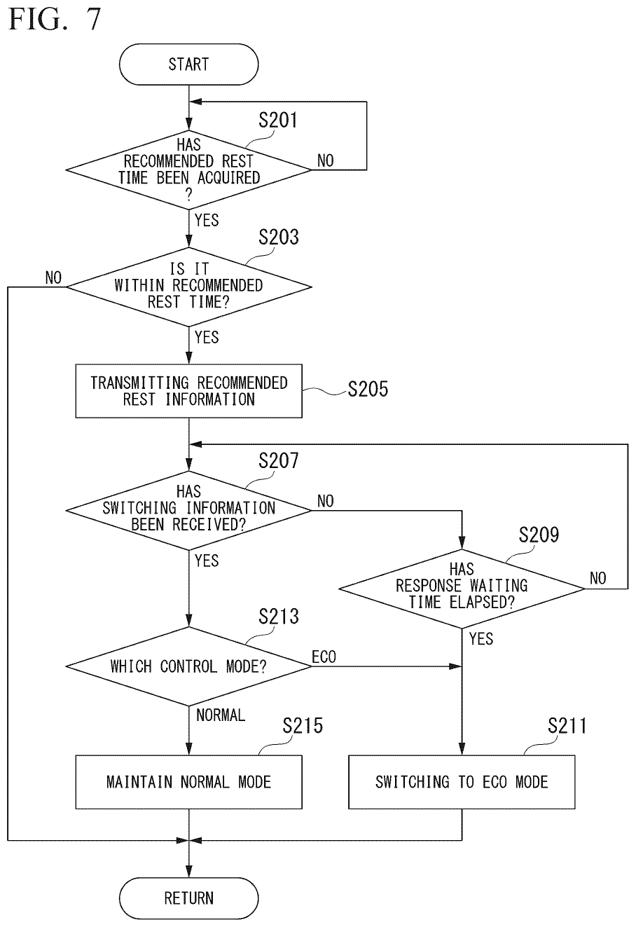

Next, the notification unit 133 transfers the recommended rest time set by the determination unit 132 to the ECU 200 (step S117). In this manner, the determination device 100 ends the processing shown in FIG. 6. Next, processing of the ECU 200 will be described. FIG. 7 is a flowchart showing an example of processing in the ECU 200.

In the ECU 200, the mode setting unit 230 determines whether or not the recommended rest time notified by the determination device 100 has been acquired (step S201). If it is determined that the recommended rest time has not been acquired, the providing unit 240 repeats the processing of step S201. If it is determined that the recommended rest time has been acquired, the providing unit 240 determines whether or not the current time is within the recommended rest time (step S203).

If the providing unit 240 determines that the current time is not within the recommended rest time (the current time is within the recommended rest time), the ECU 200 ends the processing shown in FIG. 7 as it is. If it is determined that the current time is within the recommended rest time, the providing unit 240 generates recommended rest information according to the acquired recommended rest time and transmits the information to the input/output interface 43 (step S205). At this time, the providing unit 240 sets a response waiting time during which the providing unit 240 waits for transmission of switching information as a response from the input/output interface 43.

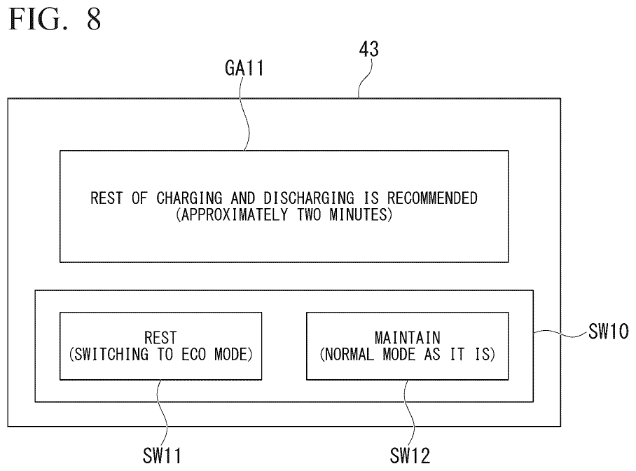

The input/output interface 43 to which the recommended rest information has been transmitted displays the recommended rest information. Here, an image when the mode setting unit 230 has set the control mode to the normal mode is shown. FIG. 8 is a diagram showing an example of a display screen of the input/output interface 43 that displays the recommended rest information. A message image GA11, and a rest designation switch SW11 and a maintain designation switch SW12 as a mode designation switch SW10 are displayed on the input/output interface 43 that displays the recommended rest information.

The message image GA11 displays a message that includes a text “A rest of charging and discharging is recommended” along with a text “(Approximately two minutes)” indicating a remaining time of the recommended rest time. When the message image GA11 is viewed, the occupant recognizes that a control to reduce a load on the lithium metal battery 10 is recommended.

The occupant can reduce the load on the lithium metal battery 10 by, for example, switching the control mode from the normal mode to the eco-mode. On the other hand, when the control mode is switched to the eco-mode, an output of the driving motor 41 drops, or cooling power of the air conditioning device 42 decreases.

If the occupant sets the eco-mode that reduces a load on the lithium metal battery 10 following a recommendation of the determination device 100, the occupant operates the rest designation switch SW11 of the mode designation switch SW10. On the other hand, if the occupant wishes to maintain the normal mode despite the recommendation of the determination device 100, the occupant operates the maintain designation switch SW12 of the mode designation switch SW10. The input/output interface 43 generates switching information based on the operation of the mode designation switch SW10 by the occupant and transmits it to the ECU 200.

In the ECU 200, after the providing unit 240 transmits the recommended rest information in step S205, the receiving unit 250 determines whether or not the switching information transmitted by the input/output interface 43 has been received and accepted (step S207). If the receiving unit 250 determines that the switching information has been received, and if the received switching information is maintain execution information based on an operation of the maintain designation switch SW12, the mode switching unit 260 maintains the normal mode set in the control mode (step S215). If the received switching information is switching execution information based on an operation of the rest designation switch SW11, the mode switching unit 260 switches the normal mode set as the control mode to the eco-mode (step S211). Thereafter, the ECU 200 ends the processing shown in FIG. 8.

If it is determined in step S207 that the switching information has not been received, the receiving unit 250 determines whether or not the response waiting time has elapsed (step S213). If it is determined that the response waiting time has not elapsed, the receiving unit 250 repeats the processing of step S207. If it is determined that the response waiting time has elapsed, the mode switching unit 260 switches the control mode to the eco-mode (step S215). Thereafter, the ECU 200 ends the processing shown in FIG. 8.

The control device 60 of the embodiment generates and acquires a relaxation polarity of the voltage of the lithium metal battery 10 based on the charge-discharge history of the lithium metal battery 10, and determines a recommended-suppression time based on a rate of change of the voltage in the short time constant range in the relaxation curve. Therefore, deterioration of the lithium metal battery can be suppressed, and a lifespan of the lithium metal battery 10 can be prolonged.

The embodiment described above can be expressed as follows.

A determination device includes: a storage medium that stores computer-readable instructions; and a processor connected to the storage medium.

The processor is configured to execute the computer-readable instructions to:
acquire a relaxation curve of voltage of a lithium metal battery having a negative electrode containing lithium; and
determine a recommended-suppression time of recommending suppression of charging and discharging of the lithium metal battery based on a rate of change of voltage in a short time constant range corresponding to a range of a short time constant in the relaxation curve.

While preferred embodiments of the invention have been described and illustrated above, it should be understood that these are exemplary of the invention and are not to be considered as limiting. Additions, omissions, substitutions, and other modifications can be made without departing from the spirit or scope of the invention. Accordingly, the invention is not to be considered as being limited by the foregoing description, and is only limited by the scope of the appended claims.

What is claimed is:

1. A determination device comprising a processor, the processor being configured to:
acquire a relaxation curve of voltage of a lithium metal battery having a negative electrode containing lithium; and
determine a recommended-suppression time of recommending suppression of charging and discharging of the lithium metal battery based on a rate of change of voltage in a short time constant range corresponding to a range of a short time constant in the relaxation curve.

2. The determination device according to claim 1, wherein
the processor is configured to acquire the relaxation curve generated based on a charge-discharge history of the lithium metal battery.

3. The determination device according to claim 1, wherein
the processor is configured to determine that the recommended-suppression time is longer when the rate of change is less than or equal to a specified value than when the rate of change exceeds the specified value.

4. The determination device according to claim 1, wherein
the processor is configured to determine the recommended-suppression time by referring to a suppression time control map in which the recommended-suppression time is set to be longer when the rate of change is less than or equal to a specified value than when the rate of change exceeds the specified value.

5. The determination device according to claim 1, wherein
the processor is configured to switch a control mode between a first control mode of controlling the lithium metal battery and a second control mode in which a load on the lithium metal battery is smaller than that in the first control mode.

6. The determination device according to claim 5, wherein
the processor is configured to provide information related to the recommended-suppression time to a user and accepts a designation of the control mode by the user, and
the processor is configured to switch the control mode based on the designation.

7. The determination device according to claim 6, wherein
the information related to the recommended-suppression time includes the recommended-suppression time.

8. The determination device according to claim 1, wherein
the lithium metal battery is mounted in a vehicle.

9. A determination method causing a computer to:
acquire a relaxation curve of voltage of a lithium metal battery having a negative electrode containing lithium; and
determine a recommended-suppression time of recommending suppression of charging and discharging of the lithium metal battery based on a rate of change of voltage in a short time constant range corresponding to a range of a short time constant in the relaxation curve.

10. A computer-readable non-transitory storage medium storing a program, the program causing a computer to:
acquire a relaxation curve of voltage of a lithium metal battery having a negative electrode containing lithium; and
determine a recommended-suppression time of recommending suppression of charging and discharging of the lithium metal battery based on a rate of change of voltage in a short time constant range corresponding to a range of a short time constant in the relaxation curve.
